(19) United States
(12) Patent Application Publication
(10) Pub. No.: US 2016/0069937 A1
(43) Pub. Date: Mar. 10, 2016

(54) VOLTAGE SENSING UNIT FOR SENSING VOLTAGE OF HIGH-POWER LINES USING A SINGLE-CONTACT POINT AND METHOD OF USE THEREOF

(71) Applicant: AWESENSE WIRELESS INC., Vancouver (CA)

(72) Inventors: Thomas Edward Johnson, Lake Country (CA); Jake Stanley Bobowski, Lake Country (CA); Rick Slamka, West Kelowna (CA)

(21) Appl. No.: 14/888,417

(22) PCT Filed: May 2, 2014
(86) PCT No.: PCT/CA2014/000410

§ 371 Date: Oct. 30, 2015

Related U.S. Application Data
(60) Provisional application No. 61/818,851, filed on May 2, 2013.

(51) Int. Cl. G01R 19/00; G01R 15/16

(52) U.S. Cl. CPC G01R 19/0084; G01R 15/16

(57) ABSTRACT

A method is provided of ascertaining an unknown line (conductor) voltage at point X on a power line within an electrical grid comprises collecting raw voltage at or about Point X using a sensor; gathering additional data from data collection sources upstream (comprising, for example a substation) and/or downstream (comprising, for example, smart meters) to Point X (constraining data); using raw voltage, and environment and line data (comprising at least one of GPS location of sensor, GIS data of the electrical grid, phase, type of conductor, total load on conductor), to calculate voltage range at Point X; and using constraining data sequentially to bind (narrow and tighten) the voltage range from a determined range of possibilities to a likely absolute voltage measurement.

### FIELD OF THE INVENTION

The present invention to the field of power monitoring and devices to achieve such means within a power grid.

### BACKGROUND OF THE INVENTION

In the generation, transmission, and distribution of electric power it is important to monitor line voltage, line current, and the phase between voltage and current (power factor). Most monitoring in the electric distribution grid is done at generation nodes and at large loads, while independent monitoring on transmission or distribution lines has been limited. However, the electric grid is evolving into a highly sophisticated and complex network as smaller generation nodes are added to the grid. The term ‘smart grid’ is now used to capture the sophisticated monitoring and control that is being deployed to improve the efficiency and stability of the grid.

Electrical utilities need to monitor their power lines to determine when lines are down or in need of repair, and when power transmission to specific areas needs to be re-routed. Transmission lines route high-voltage electrical power from power plants to main regional stations and local substations. Distribution lines route high-voltage electrical power from substations to end users. In many areas, such lines are above ground exposed to the natural elements. Thus, high winds, falling trees or other forces occurring during storms or natural disasters may de-energize or “knock out” a line.

Some electrical utility companies employ Supervisory Control—and Data Acquisition (SCADA) systems with automatic sectionalizing procedures to sense the activities of their power lines and react automatically to line failures. Typically, substations have incoming and outgoing high-voltage transmission lines which feed transformers that step down the voltage (i.e., 12 kV) for distribution to end user residences and businesses. Previously, when a power line is knocked down, a coupled voltage transformer (CVT) typically senses the loss of voltage. The CVT has a primary winding connected directly to the 115 kV line and a secondary winding driving a relay to a normally open position. When the line is knocked down, the signal across the primary winding is discontinued causing the signal on the secondary winding to discontinue. The loss of signal on the secondary winding closes the relay, starting a motor that opens switches on all de-energized 115 kV lines at the substation.

The electrical utility monitors the CVT signals via remote communication within the SCADA systems to determine which lines in a region are active. A failed power line is bypassed, when possible, and power re-routed through other lines. The CVT devices are expensive devices directly connected to power lines. The power lines need to be shut down, when possible, to install and replace such devices.

As monitoring features are enhanced in the electric grid, demand is increasing for field deployable sensors with wireless backhauls. A remote sensor can now be placed on any transmission or distribution wire to collect real time load data which is transmitted wirelessly back to a central monitoring station. These sensors can measure the current, voltage and power factor of individual high voltage lines which a few years ago was not possible. It is important that sensors which clip to wires are easy to install, safe, reliable, and accurate. Accurate measurement of current is relatively common and easily made using a current loop which couples to the magnetic field around the wire. Therefore current can easily be measured on a single conductor without contacting the conductor. On the other hand, voltage, also called potential, is much more difficult to measure on a single conductor because potential has to be reference to a second conductor. Standard voltage measurements require two points of contact across two conductors making this kind of measurement dangerous at high voltages.

One non-intrusive way of detecting the presence of electrical signals is to detect the electric field (E-field) surrounding the lines carrying the signal. There are E-field detectors known for detecting low voltage (i.e. 440 volts or less) activity. One such low voltage sensor device is manufactured by Radio Shack under the brand name Micronta™. This and other low voltage sensors over-saturate in the presence of high voltage signals (such as the approximately 2000 volts or higher contemplated by the present invention). These low-voltage sensors also have a poor response to voltage transients when over-saturated and have limited use. There is also the issue of accuracy: low cost sensors detect whether there is a voltage or not and provide an estimate of the voltage only. Accuracy takes a back seat to cost (for example, a simple sensor used to locate a hidden wire in a wall). Accordingly, there is a need for a non-contact or single contact apparatus/sensor which can measure high-voltage signals, is accurate and can be used by a utility provider. This need has not been previously met.

It is an object of the present invention to obviate or mitigate the above disadvantages.

### SUMMARY OF THE INVENTION

It is an object of the present invention to provide computer implemented methods of computing voltage at a power line within an electrical grid:

a) wherein there is no substation, no downstream (end of line feeder) measuring means (such as for example.smart meters)—and wherein computing of voltage is achieved within a fully computational voltage sensing unit, as a single contact on the power line; OR

b) wherein there is a substation with voltage measuring capacity but no downstream (end of feeder) voltage measuring means (such as for example, smart meters)—and wherein computing of voltage is achieved by i) collecting raw voltage data in a voltage sensing unit on the power line at Point X (such as, for example, a simple voltage gathering sensor, and which need not necessarily be a fully computational voltage sensing unit); ii) transmitting raw voltage data to a server on a computing system remote from the sensor (such as for example, in a Cloud), said computing system comprising a microprocessor; and iii) gathering additional data from substation to Point X (constraining data); iv) using raw voltage, and environment and line data (comprising at least one of GPS location of sensor, GIS data of the electrical grid, phase, type of conductor, total load on conductor), to calculate voltage range at Point X; and v) using constraining data sequentially to bind (narrow and tighten) the voltage range from a determined range of possibilites to a likely true absolute voltage measurement at Point X.OR

c) wherein there is a substation with voltage measuring capacity and there is at least one downstream (end of feeder) voltage measuring means (such as for example, .a smart meter)—and wherein computing of voltage at Point X is achieved by i) collecting raw voltage data in a voltage sensing unit on the power line (such as, for example, a simple voltage gathering sensor, and which need not necessarily be a fully computational voltage sensing unit); ii) transmitting raw voltage data to a server on a computing system remote from the sensor (such as for example, in a Cloud), said computing system comprising a microprocessor; and iii) gathering additional data from substation and at least one downstream source to Point X (constraining data); iv) using raw voltage, and environment and line data (comprising at least one of GPS location of sensor, GIS data of the electrical grid, phase, type of conductor, total load on conductor), to calculate voltage range at Point X; and v) using constraining data sequentially to bind (narrow and tighten) the voltage range from a determined range of possibilites to a likely absolute voltage measurement . . .

There are described herein a plurality of computer enabled methods of computing voltage at a point on a power line, the steps of which may be conducted:

a) on and within the actual power line voltage sensor, said sensor being a fully computational voltage line sensor (sensing unit); which acquires voltage data and which comprises a shielded enclosure hosting a bank of capacitors comprising at least two capacitors mounted in parallel, each of the at least two capacitors being controlled by a corresponding switch, the bank of capacitors having a first connecting contact and a second connecting contact; operatively connecting one of the two connecting contact of the voltage sensing unit to the line; for each given capacitor of the at least two capacitors; selecting the given capacitor using a corresponding switch; measuring a corresponding voltage between the two connecting contacts; determining the voltage of the line using the measured voltages; or

b) within a server on a computing system remote from the sensor (such as for example, in a Cloud), said computing system comprising a microprocessor, and wherein said sensor transmits data to the server

As such, the present invention provides, in one aspect hardware: a voltage sensing unit for sensing a voltage of a power line using a single contact, the voltage sensing unit comprising: a shielded enclosure comprising a bank of capacitors, the bank of capacitors comprising at least two capacitors mounted in parallel, each of the at least two capacitors being controlled by a corresponding switch, the bank of capacitors having a first connecting contact and a second connecting contact; a line connector operatively connected to one of the two connecting contacts for operatively connecting the voltage sensing unit to the line; two voltage measuring contacts connected to the first connecting contact and the second connecting contact, the two voltage measuring contacts for receiving a voltage measuring unit.

In one aspect, within a fully computational voltage line sensor (sensing unit), the method steps of computing voltage at the power line within the electrical grid (as described further herein) occur.

In another aspect of the invention, wherein it is desired that sensor hardware be simpler and not comprise some or all of the computational (processor) capabilities, the method steps of computing voltage at the power line within the electrical grid (as described further herein) occur on a processor remote from the sensor and to which the senor transmits voltage data.

In either case, the present invention further provides, computer implemented methods of computing voltage at a power line within an electrical grid, such methods being implemented either within the sensor or on a processor remote from the sensor and to which the sensor transmits one or both of i) raw voltage data or ii) processed voltage data, such methodologies being analogous, and in accordance with the steps and formulae provided herein, regardless.

In one aspect of the invention, a method is provided of ascertaining an unknown line (conductor) voltage at point X on a power line within an electrical grid which comprises:

a) collecting raw voltage at or about Point X using a sensor;

b) gathering additional data from data collection sources upstream (comprising, for example a substation) and/or downstream (comprising, for example, smart meters)to Point X (constraining data);

c) using raw voltage, and environment and line data (comprising at least one of GPS location of sensor, GIS data of the electrical grid, phase, type of conductor, total load on conductor), to calculate voltage range at Point X; and

d) using constraining data sequentially to bind (narrow and tighten) the voltage range from a determined range of possibilites to a likely absolute voltage measurement.

The present invention provides, in one embodiment, a method for sensing a voltage of a power line using a single contact, the method comprising: providing a voltage sensing unit, the voltage sensing unit comprising a shielded enclosure hosting a bank of capacitors comprising at least two capacitors mounted in parallel, each of the at least two capacitors being controlled by a corresponding switch, the bank of capacitors having a first connecting contact and a second connecting contact; operatively connecting one of the two connecting contact of the voltage sensing unit to the line; for each given capacitor of the at least two capacitors; selecting the given capacitor using a corresponding switch; measuring a corresponding voltage between the two connecting contacts; determining the voltage of the line using the measured voltages.

The present invention provides, in another embodiment, a system for sensing a voltage of a power line using a single contact on said line, which comprises:

a) a voltage sensing unit for sensing a voltage of a power line using a single contact, the voltage sensing unit comprising: a shielded enclosure comprising a bank of capacitors, the bank of capacitors comprising at least two capacitors mounted in parallel, each of the at least two capacitors being controlled by a corresponding switch, the bank of capacitors having a first connecting contact and a second connecting contact; a line connector operatively connected to one of the two connecting contacts for operatively connecting the voltage sensing unit to the line; two voltage measuring contacts connected to the first connecting contact and the second connecting contact, the two voltage measuring contacts for receiving a voltage measuring unit; b) a means to calibrate the at least two capacitors; c) a microcontroller circuit; d) a transceiver; e) storage memory for data; and f) a means to communicate voltage data.

The present invention provides, in another embodiment, a method for sensing a voltage of a power line using a single contact, the method comprising: providing a voltage sensing unit (the sensor), the voltage sensing unit comprising a shielded enclosure hosting a bank of capacitors comprising at least two capacitors mounted in parallel, each of the at least two capacitors being controlled by a corresponding switch, determining an unknown stray capacitance between a neutral conductor and the sensor (Cg) by measuring a set of voltages corresponding to differing switch positions and fitting measurements so determined to a non-linear circuit model.

The present invention provides, in another embodiment, a method for sensing a voltage of a power line using a single contact, the method comprising: providing a fully computational voltage sensing unit, the voltage sensing unit comprising a shielded enclosure hosting a bank of resistors comprising at least two resistors mounted in parallel, each of the at least two resistors being controlled by a corresponding switch, determining an unknown stray capacitance between a neutral conductor and the sensor (Cg) by measuring a set of voltages corresponding to differing switch positions and fitting measurements so determined to a non-linear circuit model.

The present invention provides, in another embodiment, a method for sensing a voltage of a power line using a single contact, the method comprising: providing a voltage sensing unit (the sensor), the voltage sensing unit comprising a shielded enclosure hosting a bank of capacitors and/or resistors comprising at least two capacitors and/or resistors mounted in parallel, each of the at least two capacitors and/or resistors being controlled by a corresponding switch, determining an unknown stray capacitance between a neutral conductor and the sensor (Cg) by measuring a set of voltages corresponding to differing switch positions and fitting measurements so determined to a non-linear circuit model.

The sensor, voltage measuring methods, calibration methods and system of the present invention afford many advantages. This invention provides a way to make accurate voltage measurements using a method that only requires a sensor to have one contact with one conductor. The parasitic capacitance of the sensor to a second conductor is used to create a second reference which enables potential to be measured between the conductors. The parasitic capacitance from the sensor to the second conductor is referred to herein as Cg. This capacitance is highly variable and depends on the spacing of the wires and the placement and orientation of the sensor. The capacitance Cg is also dependent on environmental conditions which create movement in the wires (wind) and the thermal expansion of the wires which changes wire sag.

As such, a significant aspect of this invention is the calibration method(s) which is used to determine the parasitic capacitance Cg. An accurate calibration method to determine Cg is critical to obtaining accurate voltage measurements and such methods are described fully herein.

An elegant and simple method is provided herein to accurately measure voltage using a single contact to one conductor. The sensor comprises a sensing plate which couples to the second conductor through Cg. The sensor is guarded by a shield. Enclosed within this shield is a bank of calibrated capacitors which can be switched in to change the capacitor divide ratio. Using a calibrated and shielded capacitor bank provides a way to make accurate voltage measurements without knowing any of the physical parameters in the system such as conductor spacing and the distance to earth ground. The voltage sensor also is easily deployable in any field situation. The single contact improves the safety of deploying the sensor and avoids making contact between two conductors which is required in other voltage measurement methods.

### DESCRIPTION OF THE FIGURES

The following figures set forth embodiments in which like reference numerals denote like parts. Embodiments are illustrated by way of example and not by way of limitation in all of the accompanying figures.

FIG. 1 is a schematic of a circuit model for voltage measurement of a high-power line using a single-contact point sensor according to an embodiment of this invention;

FIG. 2 is a schematic of a simplified circuit model for voltage measurement of a high-power line using a single-contact point according to an embodiment of this invention;

FIG. 3 is schematic of a single-contact point voltage sensor comprising a switched capacitor bank and a switched resistor bank;

FIG. 4 is a graph representing experimental measurements using a calibrated sensor wherein the x-axis is the line voltage V_{L} and y-axis is the measured voltage Vₘ;

FIG. 5 is a further schematic of a circuit model for voltage measurement of a high-power line using a single-contact point sensor according to an embodiment of this invention;

FIG. 6 is further schematic of a circuit model for voltage measurement of a high-power line using a single contact-point sensor according to an embodiment of this invention.

FIG. 7 is a further schematic of a circuit model with an additional capacitive voltage divider which allows the voltage sensing unit to be used in very high-voltage applications without compromising the sensitivity of the sensor;

FIG. 8 is a graph showing the linearity test of sensing voltages;

FIG. 9 is a graph showing estimated capacitance Cₒ as a function of the applied line voltage;

FIG. 10 is a graph showing estimated capacitance C_{g} as a function of the applied line voltage;

FIG. 11 is a graph showing the estimated line voltage measured by the single-contact voltage sensor in a blind context compared to the actual applied line voltage. This is measured by the single-contact voltage sensor in a blind test compared to the actual applied line voltage. The different colour points correspond to different initial parameter values used in the non-linear fit routine. In this example, the estimated line voltage is always within 10% of the actual line voltage;

FIG. 12 is a graph showing the linear relationship between Vₘ and V_{L} when the voltage sensing unit is configured for high-voltage measurements using an additional secondary capacitive divider; and

FIG. 13 is an electrical grid schematic.

### PREFERRED EMBODIMENTS OF THE INVENTION

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

The algorithms and displays with the applications described herein are not inherently related to any particular computer or other apparatus. Various general-purpose systems may be used with programs in accordance with the teachings herein, or it may prove convenient to construct more specialized apparatus to perform the required machine-implemented method operations. The required structure for a variety of these systems will appear from the description below. In addition, embodiments of the present invention are not described with reference to any particular programming language. It will be appreciated that a variety of programming languages may be used to implement the teachings of embodiments of the invention as described herein.

An embodiment of the invention may be implemented as a method or as a machine readable non-transitory storage medium that stores executable instructions that, when executed by a data processing system, causes the system to perform a method. A sensor, connected to or in communication with an apparatus, such as a data processing system, can also be an embodiment of the invention. Other features of the present invention will be apparent from the accompanying drawings and from the detailed description which follows.

### Terms

The term “invention” and the like mean “the one or more inventions disclosed in this application”, unless expressly specified otherwise.

The terms “an aspect”, “an embodiment”, “embodiment”, “embodiments”, “the embodiment”, “the embodiments”, “one or more embodiments”, “some embodiments”, “certain embodiments”, “one embodiment”, “another embodiment” and the like mean “one or more (but not all) embodiments of the disclosed invention(s)”, unless expressly specified otherwise.

The term “variation” of an invention means an embodiment of the invention, unless expressly specified otherwise.

A reference to “another embodiment” or “another aspect” in describing an embodiment does not imply that the referenced embodiment is mutually exclusive with another embodiment (e.g., an embodiment described before the referenced embodiment), unless expressly specified otherwise.

The terms “including”, “comprising” and variations thereof mean “including but not limited to”, unless expressly specified otherwise.

The terms “a”, “an” and “the” mean “one or more”, unless expressly specified otherwise.

The term “plurality” means “two or more”, unless expressly specified otherwise.

The term “herein” means “in the present application, including anything which may be incorporated by reference”, unless expressly specified otherwise.

The term “e.g.” and like terms mean “for example”, and thus does not limit the term or phrase it explains. For example, in a sentence “the computer sends data (e.g., instructions, a data structure) over the Internet”, the term “e.g.” explains that “instructions” are an example of “data” that the computer may send over the Internet, and also explains that “a data structure” is an example of “data” that the computer may send over the Internet. However, both “instructions” and “a data structure” are merely examples of “data”, and other things besides “instructions” and “a data structure” can be “data”.

The term “respective” and like terms mean “taken individually”. Thus if two or more things have “respective” characteristics, then each such thing has its own characteristic, and these characteristics can be different from each other but need not be. For example, the phrase “each of two machines has a respective function” means that the first such machine has a function and the second such machine has a function as well. The function of the first machine may or may not be the same as the function of the second machine.

The term “i.e.” and like terms mean “that is”, and thus limits the term or phrase it explains. For example, in the sentence “the computer sends data (i.e., instructions) over the Internet”, the term “i.e.” explains that “instructions” are the “data” that the computer sends over the Internet.

The term “voltage sensing unit” is used interchangeably herein with “sensor” and “voltage sensor”. It is to be understood that two different types of voltage sensors are described for use with the methods herein: one is a simple line sensor (with few if any processing or computational abilities) and which collects and transmits to a remote server, raw voltage information. It is at the remote server that the raw voltage data is combined with other data, preferably with constraints, to calculate actual voltage at a selected point on an electrical power line. The other sensor described herein is referred to interchangeably as a “fully computational sensor”. Not only does this sensor collect raw voltage data, it optionally collects and aggregates other data and, in accordance with the methods described herein, calculates actual voltage at a selected point on an electrical power line. The simple line sensor offloads some or all computation fucntions to a remote server/processor.

The fully computational sensor offlods little if any of the processing steps. Preferably, the latter sensor comprising: a shielded enclosure comprising a bank of capacitors, the bank of capacitors comprising at least two capacitors mounted in parallel, each of the at least two capacitors being controlled by a corresponding switch, the bank of capacitors having a first connecting contact and a second connecting contact; a line connector operatively connected to one of the two connecting contacts for operatively connecting the voltage sensing unit to the line; two voltage measuring contacts connected to the first connecting contact and the second connecting contact, the two voltage measuring contacts for receiving a voltage measuring unit; b) a means to calibrate the at least two capacitors; c) a microcontroller circuit; d) a transceiver; e) storage memory for data; and f) a means to communicate voltage data.

Preferably, an exemplary flat metal plate is used as the sensing plate to couple to the electric field between the non-contacted wire and the sensor. Capacitance Cg is the capacitance between the non-contacted wire and the sensing plate. There are many possible types of sensing plate within the scope of the invention. Examples include a metal plate on a post that positions the sensing plate away from the body of the sensor. In this configuration, Cg can be increased while decreasing Co. The shape of the sensing plate can also vary. For example, the plate may be conical, spherical, semi-spherical, or tapered. A flat sensing disk on a post has been found to provide a good compromise between maximizing Cg which is important for accuracy and the disk is also easy to implement and manufacture.

Any given numerical range shall include whole and fractions of numbers within the range. For example, the range “1 to 10” shall be interpreted to specifically include whole numbers between 1 and 10 (e.g., 1, 2, 3, 4, . . . 9) and non-whole numbers (e.g. 1.1, 1.2, . . . 1.9).

Where two or more terms or phrases are synonymous (e.g., because of an explicit statement that the terms or phrases are synonymous), instances of one such term/phrase does not mean instances of another such term/phrase must have a different meaning. For example, where a statement renders the meaning of “including” to be synonymous with “including but not limited to”, the mere usage of the phrase “including but not limited to” does not mean that the term “including” means something other than “including but not limited to”.

Neither the Title (set forth at the beginning of the first page of the present application) nor the Abstract (set forth at the end of the present application) is to be taken as limiting in any way as the scope of the disclosed invention(s). An Abstract has been included in this application merely because an Abstract of not more than 150 words is required under 37 C.F.R. section 1.72(b). The title of the present application and headings of sections provided in the present application are for convenience only, and are not to be taken as limiting the disclosure in any way.

Numerous embodiments are described in the present application, and are presented for illustrative purposes only. The described embodiments are not, and are not intended to be, limiting in any sense. The presently disclosed invention(s) are widely applicable to numerous embodiments, as is readily apparent from the disclosure. One of ordinary skill in the art will recognize that the disclosed invention(s) may be practiced with various modifications and alterations, such as structural and logical modifications. Although particular features of the disclosed invention(s) may be described with reference to one or more particular embodiments and/or drawings, it should be understood that such features are not limited to usage in the one or more particular embodiments or drawings with reference to which they are described, unless expressly specified otherwise.

No embodiment of method steps or product elements described in the present application constitutes the invention claimed herein, or is essential to the invention claimed herein, or is coextensive with the invention claimed herein, except where it is either expressly stated to be so in this specification or expressly recited in a claim.

The invention can be implemented in numerous ways, including as a method, an apparatus, a system, a computer readable medium such as a computer readable storage medium or a computer network wherein program instructions are sent over optical or communication links. In this specification, these implementations, or any other form that the invention may take, may be referred to as systems or techniques. A component such as a processor or a memory described as being configured to perform a task includes both a general component that is temporarily configured to perform the task at a given time or a specific component that is manufactured to perform the task. In general, the order of the steps of disclosed processes may be altered within the scope of the invention.

While not intending to be limiting, there are three main case scenarios for voltage measuring and for which the methods and sensors of the invention are particularly useful:

A. Rural parts of the world where no sub-station measurement equipment exists and no smart meters exist at the end of a line feeder.

B. Regions where sub-station has measurement equipment, but there are no downstream measuring points available (i.e. no smart meters)

C. Regions (generally First World or Western regions) where sub-station and homes/business have measurement equipment (Smart meters at the homes/businesses)

Within the framework of the above three case scenarios, the following are prefered computational structures (i.e. where voltage computation can be done):

1. Voltage computation is done on the Sensor—Scenario A above.

2. Voltage computation is done remote from the sensor (for example in the Cloud)—Scenario B or C above

3. Voltage computation is done remote from sensor—Scenario C above

Use Case A: Sensor Operates Independently

A method of computing voltage at a power line within an electrical grid wherein there is no substation, no downstream (end of line feeder) measuring means (such as for example, smart meters)—and wherein computation of voltage is achieved within a fully computational voltage sensing unit, as a single contact on the power line, said method comprises:

a) collecting a sampled signal from power line (Vm) using a sensor, said sensor comprising a sensing plate which couples to a second conductor through Cg (parasitic capacitance from the sensor to the second conductor), said sensor being guarded by a shield within which is a bank of calibrated capacitors;

b) switching calibrated capacitors to change a capacitor divide ratio; and

c) calculating voltage at sensor.

In this way, the sampled signal (Vm) is processed locally in the actual sensor unit and applies factory calibration as well as estimates of Cg using predetermined constraints on the admissible range for Cg and the line voltage. The sensor unit then transmits/sends calibration voltage, current and power factor measurements back to a remote site, a central monitoring site. Reference to “remote site” simply means “not on sensor” but otherwise an application that runs on a server at a location. This location may be behind a user's firewall or at a data center like Rackspace, etc . . .

“Cloud” simply refers to refers to a computing hardware machine or group of computing hardware machines commonly referred as a server connected through a communication network such as the Internet, an intranet, a local area network (LAN) or wide area network (WAN).

The following describes variants of the invention, wherein unit samples sensor signals and sends the raw measurements back to a central monitoring site. The central monitoring site would know the location of the sensor and apply factory calibration for the unit and determine Cg and VL using a constrained nonlinear optimizer. In other words, the processing of raw data is done remotely. This may have an advantage if a log of raw data is to be captured.

Use Case B: Additional Substation Data Available i.e. Substation Voltage

In this embodiment, substation voltage may be used to set a constraint for the optimization algorithm. For example, the line voltage in the distribution grid could be used as an upper bound for the estimated line voltage at the sensor.

In this embodiment, wherein there is a substation with voltage measuring capacity but no downstream (end of feeder) voltage measuring means (such as for example, smart meters)—and wherein computing of voltage is achieved as follows. A method of computing voltage at a power line within an electrical grid comprises i) collecting data in a voltage sensing unit on the power line (such as, for example, a simple voltage gathering sensor, and which need not necessarily be a fully computational voltage sensing unit); ii) transmitting data to a server on a computing system remote from the sensor (such as for example, in a Cloud), said computing system comprising a microprocessor; and iii)

With the fast development of cloud computing and high speed wireless technologies, it has become feasible to offload computing to the cloud infrastructure servers, e.g., remote cloud servers such as Amazon EC2.®. (elastic computer cloud) or local cloud servers such as nearby desktops. Herein, knowing information from the GIS, one can calculate what V should be at the location of one of the sensors, knowing, for example, conductor type size, and rating and the like . . .

Preferably a “remote” or “cloud based software platform” connects to a SCADA (Supervisory Control And Data Acquisition) system and possibly also to a GIS system. The software would then have the ability to determine if there are any other sensors connected to the SCADA system within the grid, and poll these sensors through the SCADA system for additional voltage information. If no other devices exist in the grid, then it would be able to poll the monitoring equipment located in the sub-statation. We can collect raw-measurements with the sensor, send this back to the cloud software

Use Case C Substation and Smart Meter Data

Within this embodiment, substation and smart meter data may be used to provide more accurate bounds on the actual line voltage at the sensor point. The accuracy of the estimation of line voltage is improved by tightening the constraint on the limits for V_{L}.

The processor may receive data froma GIS system from a SCADA system, from an MDM (Meter Data Management) system and/or from Head-End Smart Meter data collection system. In any event, in a preferred aspect, smart metering and other data data is transmitted to the processor.

Smart meters are located at the end-points of the consumer, whether it be a residential or industrial consumer. These smart meters are capable of collecting Voltage (V), Current (I), Reactive Power (VAR), and sometimes Power Factor (pf). Knowing information from the GIS what V should be can be calculated at the location of one of the sensors, wherein the conductor type size, and rating are known. In this case, Case C above, acalculation is done upstream to the sensor. In Case C, a calculation may be done downstream to the sensor. That is, the voltage at the sensor in Case B will be lower than the measurement point of the sub-station, and higher than the measurement point of the smart meter in this case, Case C. Ideally, it is important to know the GIS information. It is not required to obtain information from the smart meter itself directly, but access to data can be achieved through another means,for example either the MDM or a Head-End Smart Meter data collection system that shares the smart metering information with many applications. In both Case B & C, this additional V and VAR information will allow calculatation of energy (kWh) to a much higher accuracy (the ultimate goal).

The measurements that come from either the sub-station, or the smart meter, or both (blend of Case B & C) will computatation of the voltage measurement remotely (for example, in the Cloud), passing raw measurement data from the sensors to the cloud, and setting boundary conditions on what this V measurement could and should be based on the data collected from the various other points on the grid. To reiterate, these other points can be: the substation monitoring equipment, smart meters, or other sensors and devices located within the distribution grid.

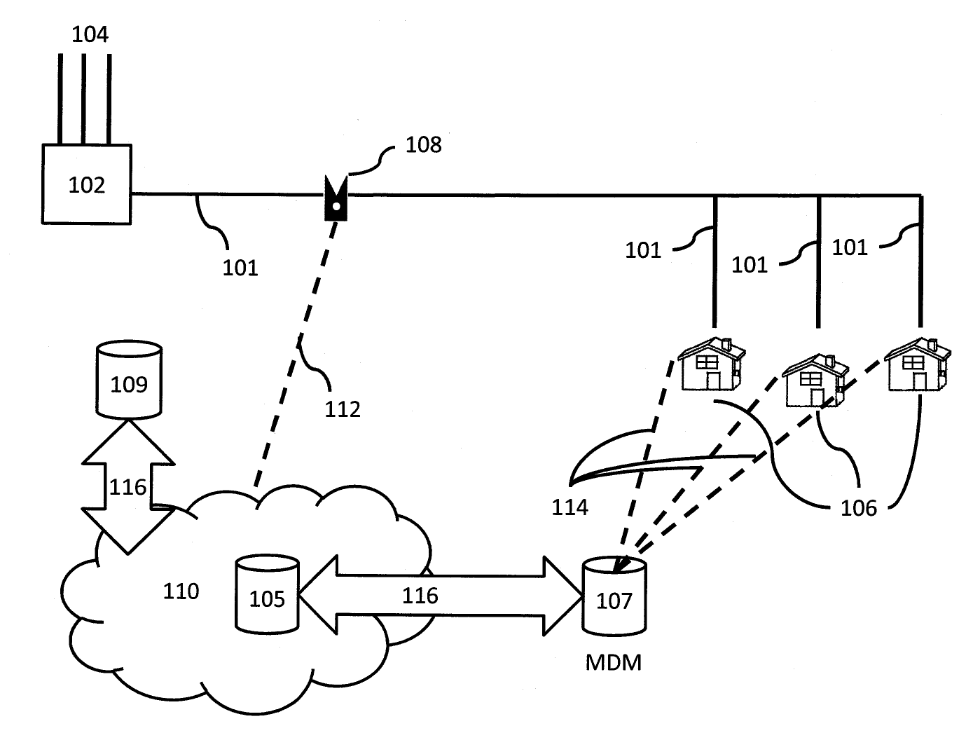

Scenario C-3 is described with reference to FIG. 13. In this case, an electrical grid shown generally at 100 having line 101 has both an upstream measurement source (substation) 102, monitoring/metering equipment at the sub-station 104 and a downstream source 106, the smart meter(s) at the home or business.

Sensor 108 is are placed on the electrical grid, at location(s) with known GPS coordinates. From the GIS data of the electrical grid, the phase is understood, as well as the type of conductor, and the total load that is on that conductor.

A simple voltage sensor collects raw voltage measurements at that location. These raw measurements are transmitted to a remote processor 110 in the cloud for computation. To constrain this computation to obtain and absolute voltage measurement at any given point, and to accurately computer voltage over time, additional data from the downstream source 106 and the upstream source 102 is captured and transmitted to processor 105 in cloud 110. There may be only one upstream source, but most likely there will be multiple downstream sources.

Since wthe location of the sensor is known, and information about the electrical grid like the type of conductor and load is known, mathematical models can be used to calculate what the voltage should be at the given point (Point X) of the sensor. A derived value is used to constrain the voltage measurement calculations such that a true true absolute voltage measurement is obtained. This method and system offloads the computation from the sensor into a remote processor, and utilizes additional data from the grid to more accurately compute the voltage measurement. This method can also be applied to calculating reactive power in the same manner.

The present disclosure relates to voltage sensors and use for high-voltage power line monitoring. Such a measurement sensor has not previously been identified with only one point of contact with the power line. As previously noted, the advantages of this are significant. In order to implement this method, there is herein provided methods of calibration of the sensor in order to obtain accurate voltage measurements (over the one point of contact).

Two types of calibration are described:

1) field calibration to determine C_{g}; and

2) factory calibration to determine Cₒ, Cₘ, Rₘ . . .

The value of C_{g} depends on the physical arrangement of the conductors and the orientation of the sensor. Factors which affect the physical arrangement of the conductors are temperature, (wire sag) and the movement or sway of the conductors in the wind.

Field calibration if preferably achieved by collecting a series of measurements with “different” combinations of capacitors selected in the capacitor bank. Such measurements are then used to solve a non-linear system of equations based on Equation (2). For field calibration, the unknowns are C_{g} and V_{L} (the line voltage).

Factory calibration is, in one preferred aspect, used to determine Cₒ, Cₘ and Rₘ. In the factory, a test bed with known line voltages can be used to make a series of measurements of Vₘ under different switch conditions in the capacitor bank. These measurements are then used to find a best fit for Equation 2. Similar to field calibration, this step requires solving a system of nonlinear equations. Various well known numerical methods can be used to solve the equations and include, but are not limited to Newton's method and the Nelder-Mead root finder algorithm.

It is an object of the present invention to calibrate a sensor where an unknown stray capacitance between a neutral conductor and the sensor (C_{g}) is determined by measuring a set of voltages corresponding to a set of capacitor bank switch positions. The set of measurements are then fitted to a nonlinear circuit model to estimate C_{g}.

It is a further object of the present invention to calibrate a sensor where C_{g} is determined by measuring a set of voltages corresponding to a set of resistor bank switch positions. The set of measurements are then fitted to a nonlinear circuit model to estimate C_{g}.

It is a further object of the present invention to calibrate a sensor where C_{g} is determined by measuring a set of voltages corresponding to a set of capacitor and resistor bank switch positions. The set of measurements are then fitted to a nonlinear circuit model to estimate C_{g}.

It is a further object of the present invention to use one of the calibration methods together with a model of the sensor, wherein an output voltage is measured which corresponds to the line voltage.

It is a further object of the present invention use a voltage measurement combined with a current measurement and wherein the power factor of the line is thereby determined.

It is a further object of the present invention to use a three phase measurement method which uses three single contact voltage sensors. It is a further object of the present invention to combine measurements of the three voltage sensors in a three phase measurement system (preferably at a remote site) to measure the voltage of each phase.

It is a further object of the present invention to use measurements of three single contact voltage sensors in a three phase measurement system and combine such measurements (preferably at a remote site) to measure power factor for each phase.

In some aspects of the invention, data is collected from one or more sensors and communicated over a wireless network allowing utility companies to quickly and economically detect losses within their electrical power grid.

Key aspects of the invention are described with reference to the figures below.

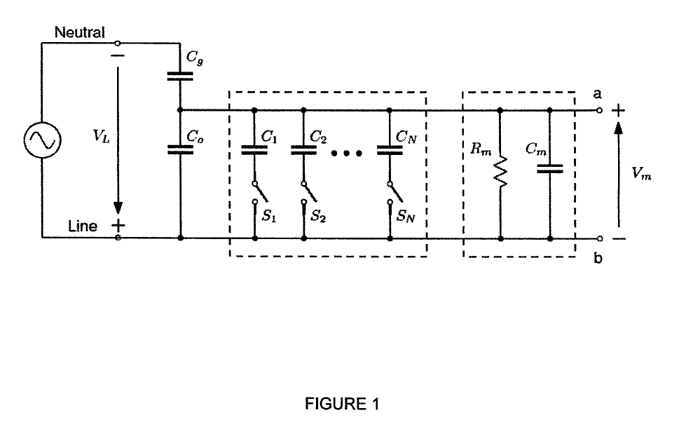

A circuit model for the single contact voltage measurement is shown in FIG. 1. In this circuit model, the following circuit elements are defined:
C_{g}: an unknown stray capacitance between the neutral conductor and the sensor
Cₒ: the intrinsic capacitance of the sensor without the capacitor bank
C₁; C₂; : : : ; C_{N}: a bank of calibrated capacitors which are switch into the circuit to make voltage measurements
Rₘ and Cₘ: the load impedance presented by the measurement buffer amplifier which contributes an error to the measured voltage Vₘ

The objective is to make an accurate voltage measurement of the line voltage V_{L} by measuring Vₘ. The measurement can be made providing all values of the components listed above are known. However, the capacitance C_{g} depends on the specific location where the sensor is installed and must be determined by a field calibration proceed. Also, C_{g} may vary over time due to changes in wire sag from temperature or from movement created by swaying conductors. The other component values in the model for Cₒ, the capacitor bank, and the measurement resistance and capacitance can be determined by a factory calibration procedure.

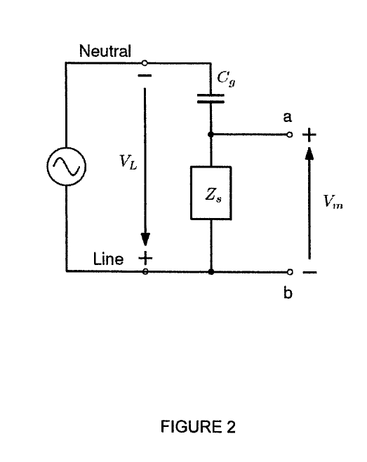

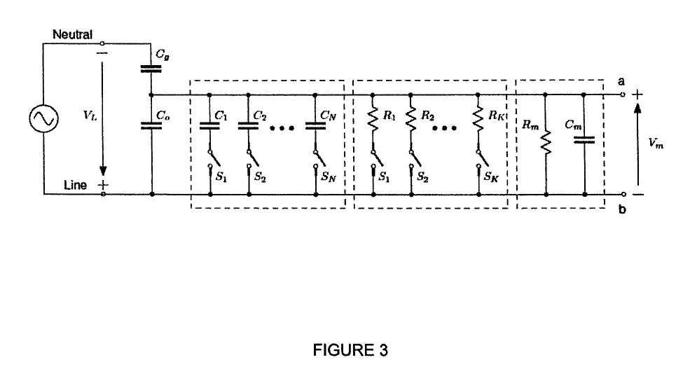

The capacitor bank components are expected to be precise capacitors with known temperature coefficients and may not require—additional calibration through a factory calibration procedure. Therefore, methods for both field and factory calibration are expected in a preferred embodiment of the sensor design. Consider the case where a factory calibration method has been employed and the values of Cₒ, C₁; C₂; : : : ; C_{N}, Rₘ, and Cₘ are all known. The remaining unknown value is C_{g} which must be determined by a field calibration procedure. A method of determining C_{g} is described next which is based on a set of measurements which are taken by changing the effective capacitance of the sensor by switching in different combinations of capacitors in the capacitor bank. A description of the field calibration procedure begins with an analysis of the circuit model shown in FIG. 1. An equivalent circuit can be derived from the model in FIG. 1 by replacing the shunt arrangement of Cₒ, the capacitor bank, and the measurement impedance with a single sensor impedance Zₛ. The simplified model is shown in FIG. 2. The impedance Zₛ can be expressed as the inverse of the admittance Yₛ where

$${Y}_{s} = \frac{1}{{R}_{m}} + jω ( {C}_{o} + {C}_{b} + {C}_{m} ) . \qquad ( 1 )$$

*In equation (1), the capacitance C_{b} is the total effective capacitance of the capacitor bank and depends on the state of the switches in the bank.

The measured voltage Vₘ relates to the line voltage V_{L} through an impedance divider created by C_{g} and Zₛ:

$${V}_{m} = - {V}_{L} \frac{{Z}_{s}}{{Z}_{s} + 1 / ( jω {C}_{g} )} = - {V}_{L} \frac{jω {C}_{g}}{jω {C}_{g} + {Y}_{s}} \qquad ( 2 )$$

Equation (1) can be used in equation (2) for Yₛ to give:

$${V}_{m} = - {V}_{L} \frac{jω {C}_{g}}{1 / {R}_{m} + jω ( {C}_{o} + {C}_{b} + {C}_{m} + {C}_{g} )} . \qquad ( 3 )$$

Further manipulation of equation (3) yields:

$${V}_{m} = - {V}_{L} \{ \begin{matrix}\frac{{ω}^{2} {C}_{g} ( {C}_{o} + {C}_{b} + {C}_{m} + {C}_{g} )}{{( 1 / {R}_{m} )}^{2} + {[ ω ( {C}_{o} + {C}_{b} + {C}_{m} + {C}_{g} ) ]}^{2}} + \\ \frac{jω {C}_{g} / {R}_{m}}{{( 1 / {R}_{m} )}^{2} + {[ ω ( {C}_{o} + {C}_{b} + {C}_{m} + {C}_{g} ) ]}^{2}}\end{matrix} \} \qquad ( 4 )$$

Equation (4) shows that the measured voltage corresponds to a scaled line voltage V_{L} with an additional phase shift that depends on the effective loading resistance of the measurement amplifier Rₘ. The operation of the sensor is seen more clearly if Rₘ is assumed to be very large relative to the capacitive reactances in the circuit. In the limit as Rₘ→∞:

$${V}_{m} = - {V}_{L} \frac{{C}_{g}}{{C}_{o} + {C}_{b} + {C}_{m} {C}_{g}} . \qquad ( 5 )$$

Under this condition, the circuit reduces to a capacitive voltage divider. The capacitance C_{g} is typically very small in the range of 1-pF or less and the bank capacitance C_{b} can be selected to provide a voltage division ratio so that Vₘ is—smaller than V_{L}. As an example, suppose a voltage division ratio of 30—is required. If C_{g} is 1 pF, Cₒ is 10 pF, and Cₘ is 10 pF, then the capacitance in the switch bank is 9 pF. Equation (4) shows that in general when the measurement resistance Rₘ of the instrumentation amplifier introduces a phase error between the measured voltage Vₘ and the line voltage V_{L}. The change in phase error as a function of a change in the capacitance C_{b} of the capacitor bank provides additional information which can improve the estimate of C_{g}. Since only the magnitude of Vₘ is measured, the magnitude is a function of both the real and imaginary parts in equation (4). If Rₘ, Cₘ, Cₒ, and C₁; C₂; : : : CN are all known through factory calibration, then Rₘ introduces additional warping in the nonlinear function which improves the accuracy of fitting a C_{g} to the measurement data. An extension of this idea is to add a resistor switch bank as shown in FIG. 3. With a resistor switch bank, additional measurements can be collected which correspond to different resistor bank settings. The measurements can then provide additional information for determining a best fit of C_{g} for the sensor model.

With reference to equation (5), in a practical application of the sensor unit it is preferred to know the value of Cₒ+Cₘ within a reasonably tight tolerance. This is because fits of Vₘ versus C_{b} data to equation (5) cannot be used to uniquely determine all three of V_{L}, C_{g}, Cₒ. Rather fits to equation (5) determine only the product V_{L}C_{g} and the sum Cₒ₊Cₘ₊C_{g}. If Cₒ+Cₘ is known accurately from a previous factory calibration, then it is possible to determine the line voltage V_{L}.

With reference to equation (5), the accuracy of the sensor is dependent on the relative ratio of C_{g} over the sum of Cₒ, Cₘ and C_{b}. The ratio (C_{g}/(Cₒ+Cₘ+C_{b}) is preferably maximized for maximum accuracy. In a typical application, a series of measurements are made with different values of bank capacitance C_{b}. From the series of measurements, an estimate is then made for Cg and the unknown line voltage V_{L} assuming Cₒ and Cₘ have been calibrated at the factory. Since there are two unknowns, the best fit depends on maximizing the resolution of the function to the value of C_{g} because C_{g} affects the degree of nonlinearity in equation (5) which in turn affects the accuracy of estimated values for C_{g} and the line voltage. The more nonlinear equation (5) is the better the accuracy.

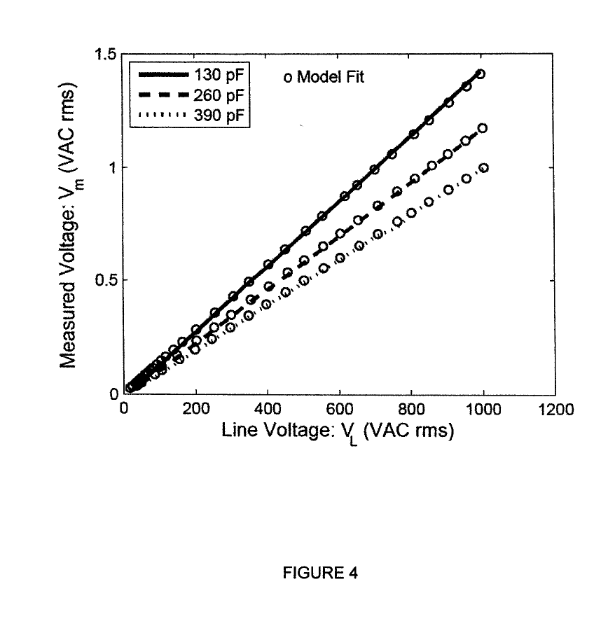

An example of measurements made with a calibrated voltage sensor is shown in FIG. 4. In this embodiment, the capacitor bank consists of three 130 pF capacitors. Measurements were first made with S₁ closed (130 pF), then S₂ was closed (260 pF), and finally all three switches were closed (390 pF). From these measurements, a nonlinear fit was made to the model is equation (4). The data in FIG. 4 shows a comparison between experimental measurements of Vₘ with the model in equation (4) as a function of line voltage. The match between the sensor voltage and the model is very good and demonstrates how accurate voltage measurements using the single-contact sensor and method of the present invention can be.

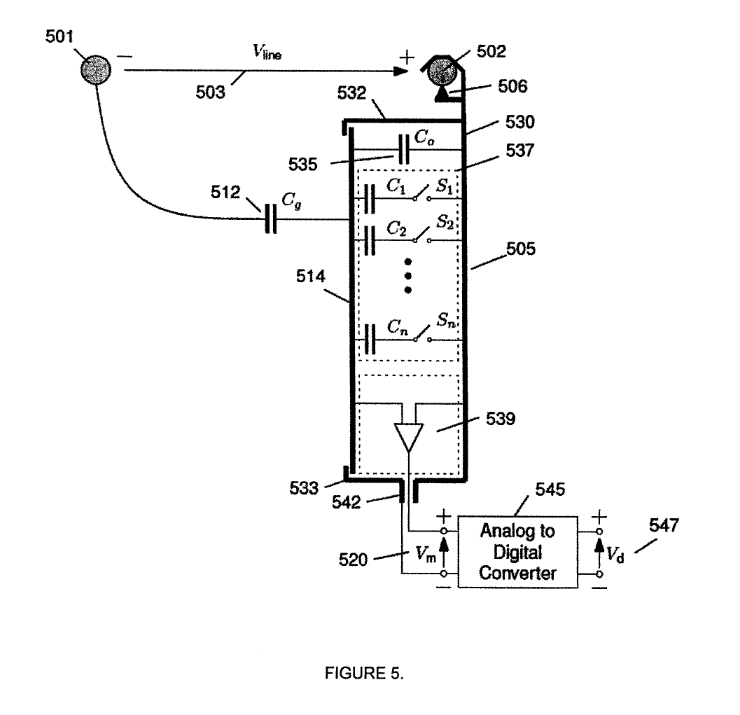

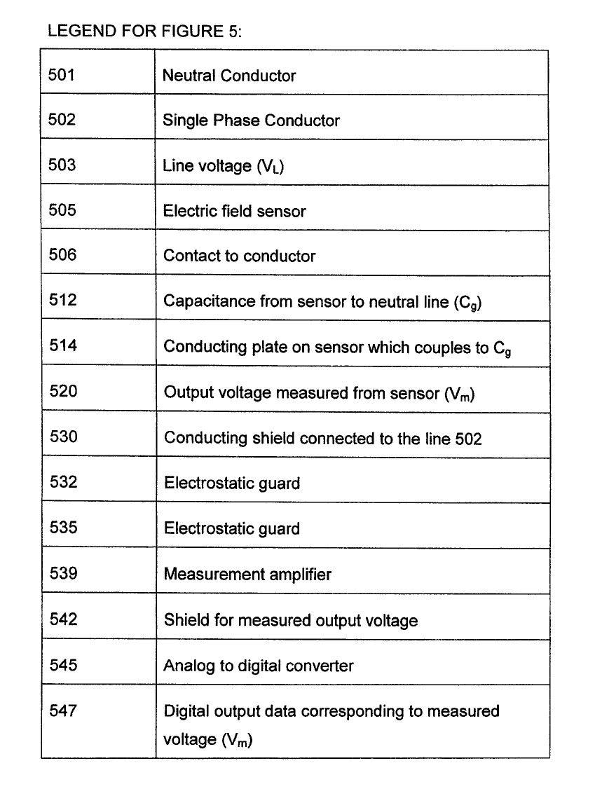

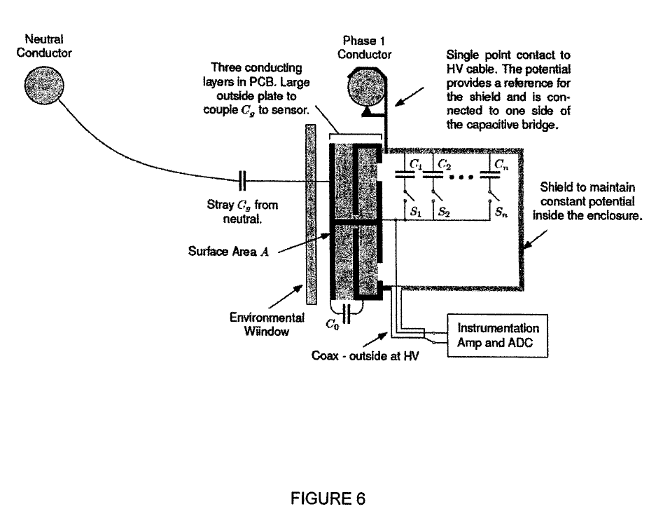

With reference to FIGS. 5 and 6, an exemplary flat metal plate is used as the sensing plate to couple to the electric field between the non-contacted wire and the sensor. Capacitance Cg is the capacitance between the non-contacted wire and the sensing plate. There are many possible types of sensing plate within the scope of the invention. Examples include a metal plate on a post that positions the sensing plate away from the body of the sensor. In this configuration, Cg can be increased while decreasing Co. The shape of the sensing plate can also vary. For example, the plat may be conical, spherical, semi-spherical, or tapered. A flat sensing disk on a post has been found to provide a good compromise between maximizing Cg which is important for accuracy and the disk is also easy to implement and manufacture.

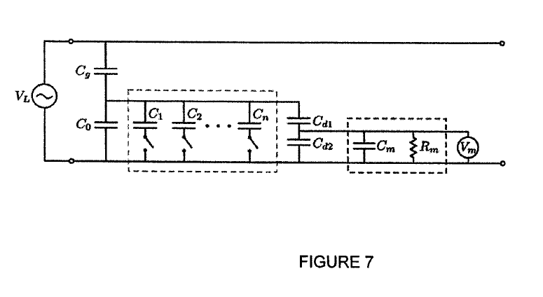

In high-voltage applications, a multistage capacitive divider can be advantageous. This is illustrated in FIG. 7. Provided that C_{d1} is selected to be comparable to Cₘ in equation (5) and C_{d2} is much greater than C_{d1}, the ratio between the line voltage V_{L} and the measured voltage Vₘ can be made arbitrarily large without compromising the sensitivity of single point contact voltage sensor. With the additional capacitive divider formed by C_{d1} and C_{d2} in place and in the limit Rₘ←∞, the full expression relating Vₘ to V_{L} is:

$${V}_{m} = {V}_{L} [ \frac{{C}_{g}}{{C}_{0} + {( \frac{1}{{C}_{d 1}} + \frac{1}{{C}_{d 2} + {C}_{m}} )}^{- 1} + {C}_{b} + {C}_{g}} ] \times ( \frac{{C}_{d 1}}{{C}_{d 1} + {C}_{d 2} + {C}_{m}} ) \qquad ( 6 )$$

In the limit that C_{d2}>>C_{d1} equation (6) simplifies to:

$${V}_{m} \approx {V}_{L} ( \frac{{C}_{g}}{{C}_{0} + {C}_{b} + {C}_{d 1} + {C}_{g}} ) \frac{{C}_{d 1}}{{C}_{d 2}} \qquad ( 7 )$$

Comparing equation (7) to equation (5) shows that the additional capacitive divider does not change the sensitivity of the voltage sensor provided that C_{d1}≈Cₘ, but reduces Vₘ by a factor of C_{d1}/C_{d2}<<1 which is desirable for high-voltage applications to avoid saturating the unity gain buffer.

The capacitive divider may be extended to more than two steps for very high voltage applications.

Software Architecture for Remote Sensing Units-Details

In accordance with one aspect of the invention, a single contact voltage sensor is a component in a remote monitoring unit which is suspended from a high voltage transmission line wire. The unit is also configured with a current sensor. Voltage and current waveforms can be simultaneously sampled to calculate power factor, another very important measurement which utility companies require to monitor the reactive power in the grid. Other measurements which can be made by post-processing raw sensor data include the harmonic content in the waveforms to calculate total harmonic distortion. Voltage and current signals should be sinusoidal, but in practice there are harmonic frequency components. The level of the harmonics should be low and require monitoring in the grid.

The voltage and current sensors provide analog signals which are sampled by an analog to digital converter (ADC). After sampling, digital representations of the voltage and current signals are available for further processing. The ADC has a sample rate which is much higher than the line frequency (for example 50 or 60 Hz) and each signal is captured as a times series. For example, N samples from the voltage and current sensors can be captured and stored as a time series with additional information including a time stamp and the location of the sensor. It should be noted that ideally the voltage and current signals are captured simultaneously by synchronized ADCs. This ensures that there is no phase error between the voltage and current waveforms. If a multiplexed ADC is used, the timing of samples needs to be controlled and post-processing can then be used to realign the raw voltage and current sensor waveforms.

After capturing records (time series) of voltage and current data from the sensors, post-processing is required to transform the data into useful outputs which an operator of a utility will want to monitor. Examples of post-processed outputs include the voltage of each phase at the monitoring point, the current in each phase at the monitoring point, the power factor at the monitoring point, and the total harmonic distortion of the voltage and current waveforms. Post-processing can be done either remotely in the remote monitor unit or in a cloud based server. The cloud based server could either be located at the central monitoring site or it may be a service provided by another vendor.

The central monitoring site for a utility consolidates sensor data from many sources including remote monitor units located in the distribution and transmission grid, smart meters at loads, and substation monitoring units. The entire set of sensor data available at the central monitoring site can provide valuable information which can be used to assist in constraining unknown parameters which are required to interpret the raw sensor data accurately. The additional sensor information available at the central monitoring site can be either uploaded to a remote monitoring unit to improve the accuracy of processing sensor data, or, the raw sensor data can be downloaded to a server in the central monitoring station and processed by software that uses data from multiple monitoring points in the network. Therefore, sensor data can be processed independently (i.e. from a single remote monitoring unit) or collectively where data from many sensors are consolidated to improve the accuracy of measurements at specific points in the grid.

Examples of different scenarios to process sensor data include:

### Independent and Local Processing in the Remote Monitoring Unit/Independent Data Which is Remotely Processed on a Server

Multiple sensor data which is consolidated at a remote server that then uploaded constraints which improve the accuracy of post-processing sensor data in a remote unit. For example, data from the remote sensor is combined with substation monitoring data and/or smart meter data from end user loads.

Multiple sensor data which is consolidated at a remote server that is applied to raw sensor data logs which have been uploaded from remote units. For example, data substation monitoring data and/or smart meter data from end user loads is used to provide constraints which are uploaded to the remote unit which improves the accuracy of estimating the line voltage.

The network scenarios described above can be considered examples of system requirement specification. The system requirements are used to design the software architecture for remote sensing unit with the single point contact voltage sensor. An example of the high level design requirements for the software is described below.

Simultaneously capture N samples of the output signals from the voltage sensor (Vm) and the current sensor (Im). The raw sensor data is consolidated into a record which includes the value of the bank capacitance Cb, the current temperature of the sensor, the time base for the samples, the location of the sensor and the serial number of the sensor.

A series of data logs is created by stepping through different values of bank capacitance (Cb). The line voltage is assumed to be constant as the bank capacitance is stepped through different values. Therefore, the latency between each step is small.

Each sensor unit has factory calibration data associated with it that includes the value of Co, the value of bank capacitances and temperature calibration data. The calibration data can be stored locally in the remote sensor, or stored remotely on a server, or mirrored in both the remote unit and on a remote server.

A programmable flag whose state is set by the central monitoring site determines whether raw sensor data logs are uploaded to the remote server or whether the remote unit should process the raw sensor data. Therefore, depending on the state of this flag, it determines where the next steps in the software flow are executed: locally or remotely.

A set of constraint ranges is associated with each unknown variable which needs to be estimated. In the voltage sensor two unknowns are the stray capacitance Cg to the non-contacted line and the unknown line voltage of the phase which is being monitored. The constraints provide bounds for each unknown variable which must be estimated using a nonlinear optimization algorithm. The accuracy of the estimated values depends on the constraint ranges. A tight bound on the range of a variable improves the accuracy of the estimated value.

Constraint ranges for Cg and the line voltage VL are predetermined by the location of the sensor in the grid. The constraint ranges can be programmed remotely from the central office or preset during installation.

The predetermined constraint ranges for unknown variables (e.g. Cg and VL) mayn be updated using additional sensor data in the grid. For example, substation voltage measurements could be used to set the upper bound on the line voltage assuming the remote sensor is located between the substation and the end user load. The voltage at the monitoring point must be less than the substation voltage assuming there are no other local generating sites feeding the distribution grid. Another adjustment on the constraint range for the line voltage could be obtained using smart meters which monitor the voltage at the end of the distribution grid. Smart meter voltage measurements could be used to set the lower bound on the line voltage which is to be estimated by the remote voltage sensor.

A nonlinear constrained optimization algorithm is used to estimate the line voltage at the location of the remote sensor unit. The inputs to the algorithm include the raw data log files for a set of bank capacitances, the temperature, the value of Co, the constraint range for Cg, and the constraint range for the line voltage. The optimizer then iterates to minimize an error function and provide estimates of Cg and the line voltage. The optimizer is either run locally in the remote unit if the remote flag is set, or it is run on a remote server.

After the line voltage is estimated, it can be combined with processed current data to estimate the power factor and the total harmonic distortion.

In one aspect, the system additionally comprises one or more network managers. Preferably, these one or more network managers which each comprise a modem capable of transmitting measurement data from the sensor over a network. In one aspect, the system additionally comprises one or more network managers which relay data from the sensors to a server via a means selected from the group consisting of cellular, satellite, WiMAX and Wifi. In one aspect, the system additionally comprises one or more network managers which aggregate and relay the data from the sensors to a server and wherein said server enables viewing of the data by a viewer via an interface. In one aspect, the system additionally comprises one or more network managers which aggregate and relay the data from the sensors to a server and wherein said server enables viewing of the data by a viewer via an interface and wherein said interface is selected from the group consisting of a desktop computer, a laptop computer, a hand-held microprocessing device, a tablet, a Smartphone, iPhone®, iPad®, PlayBook® and an Android® device.

Those skilled in the relevant art will appreciate that the invention can be practiced with any computer configurations, including hand-held devices, multiprocessor systems, microprocessor-based or programmable consumer electronics, personal computers (“PCs”), network PCs, mini-computers, mainframe computers, and the like. In one aspect, the measurement data is communicated wirelessly on a peer-to-peer network to a central network manager. In one aspect, the measurement data is collected in situ from the sensors or network managers. This can be achieved by workers on site either on the ground or using a bucket truck. In one aspect, the system comprises more than three sensors. In one aspect, the system may be temporarily field deployable on one or more supply line electrical wires and then moved and reset on other supply line electrical wires without the requirement of any wire splicing for such deployment and re-deployment.

In one aspect, the method additionally employs one or more network managers. In one aspect, the method additionally employs one or more network managers which each comprise a modem which transmits measurement data over a network. In one aspect, the method additionally employs one or more network managers which relay data from the sensor nodes to a server via a means selected from the group consisting of cellular, satellite, WiMAX and Wifi. In one aspect, the method additionally employs one or more network managers which aggregate and relay the data from the sensor nodes to a server and wherein said server enables viewing of the data by a viewer via an interface. In one aspect, the method additionally employs one or more network managers which aggregate and relay the data from the sensor nodes to a server and wherein said server enables viewing of the data by a viewer via an interface and wherein said interface is selected from the group consisting of a desktop computer, a laptop computer, a hand-held microprocessing device, a tablet, a Smartphone, iPhone®, iPad®, PlayBook® and an Android® device. Those skilled in the relevant art will appreciate that the invention can be practiced with any computer configurations, including hand-held devices, multiprocessor systems, microprocessor-based or programmable consumer electronics, personal computers (“PCs”), network PCs, mini-computers, mainframe computers, and the like. In one aspect, measurement data is communicated wirelessly on a peer-to-peer network to a central network manager. In yet another aspect, the measurement data is collected in situ from the sensor nodes or network managers. This may be achieved by workers on site either on the ground or using, for example, a bucket truck. In yet another aspect, the method uses more than three sensor nodes. In another aspect, the sensors for use in the method may be temporarily field deployable on one or more supply line electrical wires and then moved and reset on other supply line electrical wires without the requirement of any wire splicing for such deployment and re-deployment. In yet another aspect, the measurement data is transmitted wirelessly to a server; and an analysis is made to determine if a loss has occurred. In another aspect, the supply line electrical wire is a medium voltage line or a high voltage line.

In operation, if the data acquired using the sensors, system and/or method of the invention indicates possible power loss, flaws, voltage leakages or other problems, notification may be sent to a monitoring entity or to a utility. The sensors are easy to deploy electrical distribution line sensors, which, once engaged at the single point of contact, may instantly begin to relay measurement data back to central servers for post processing through the network manager (Gateway), which itself is also mobile like the measurement sensors. The entire system can be expanded, contracted, and relocated at will. Furthermore, in other aspects of the invention, there is provided enterprise software which allows users a real time dashboard with powerful analytics to help them consume large amounts of field measurement data in an effective manner.

Preferably, the sensors communicate using open standards (using for example, IEEE802.15.4) as demanded by the utility industry. Each node within the system is capable of wirelessly hopping data from a sister sensor to the end of the router device. Sensors can be placed in close proximity to one another or alternatively can be placed at distances from one another.

Within the scope of the present invention, data acquisition may preferably be controlled by a computer or microprocessor. As such, the invention can be implemented in numerous ways, including as a process, an apparatus, a system, a computer readable medium such as a computer readable storage medium or a computer network wherein program instructions are sent over optical or communication links. In this specification, these implementations, or any other form that the invention may take, may be referred to as systems or techniques. A component such as a processor or a memory described as being configured to perform a task includes both a general component that is temporarily configured to perform the task at a given time or a specific component that is manufactured to perform the task. In general, the order of the steps of disclosed processes may be altered within the scope of the invention.

The following discussion provides a brief and general description of a suitable computing environment in which various embodiments of the system may be implemented. In particular, this is germane to the network managers, which aggregate measurement data and downstream to the servers which enables viewing of the data by a user at an interface.

Although not required, embodiments will be described in the general context of computer-executable instructions, such as program applications, modules, objects or macros being executed by a computer. Those skilled in the relevant art will appreciate that the invention can be practiced with other computer configurations, including hand-held devices, multiprocessor systems, microprocessor-based or programmable consumer electronics, personal computers (“PCs”), network PCs, mini-computers, mainframe computers, and the like. The embodiments can be practiced in distributed computing environments where tasks or modules are performed by remote processing devices, which are linked through a communications network. In a distributed computing environment, program modules may be located in both local and remote memory storage devices.

A computer system may be used as a server including one or more processing units, system memories, and system buses that couple various system components including system memory to a processing unit. Computers will at times be referred to in the singular herein, but this is not intended to limit the application to a single computing system since in typical embodiments, there will be more than one computing system or other device involved. Other computer systems may be employed, such as conventional and personal computers, where the size or scale of the system allows. The processing unit may be any logic processing unit, such as one or more central processing units (“CPUs”), digital signal processors (“DSPs”), application-specific integrated circuits (“ASICs”), etc. Unless described otherwise, the construction and operation of the various components are of conventional design. As a result, such components need not be described in further detail herein, as they will be understood by those skilled in the relevant art.

A computer system includes a bus, and can employ any known bus structures or architectures, including a memory bus with memory controller, a peripheral bus, and a local bus. The computer system memory may include read-only memory (“ROM”) and random access memory (“RAM”). A basic input/output system (“BIOS”), which can form part of the ROM, contains basic routines that help transfer information between elements within the computing system, such as during startup.

The computer system also includes non-volatile memory. The non-volatile memory may take a variety of forms, for example a hard disk drive for reading from and writing to a hard disk, and an optical disk drive and a magnetic disk drive for reading from and writing to removable optical disks and magnetic disks, respectively. The optical disk can be a CD-ROM, while the magnetic disk can be a magnetic floppy disk or diskette. The hard disk drive, optical disk drive and magnetic disk drive communicate with the processing unit via the system bus. The hard disk drive, optical disk drive and magnetic disk drive may include appropriate interfaces or controllers coupled between such drives and the system bus, as is known by those skilled in the relevant art. The drives, and their associated computer-readable media, provide non-volatile storage of computer readable instructions, data structures, program modules and other data for the computing system. Although a computing system may employ hard disks, optical disks and/or magnetic disks, those skilled in the relevant art will appreciate that other types of non-volatile computer-readable media that can store data accessible by a computer system may be employed, such a magnetic cassettes, flash memory cards, digital video disks (“DVD”), Bernoulli cartridges, RAMs, ROMs, smart cards, etc.

Various program modules or application programs and/or data can be stored in the computer memory. For example, the system memory may store an operating system, end user application interfaces, server applications, and one or more application program interfaces (“APIs”).

The computer system memory also includes one or more networking applications, for example a Web server application and/or Web client or browser application for permitting the computer to exchange data with sources via the Internet, corporate Intranets, or other networks as described below, as well as with other server applications on server computers such as those further discussed below. The networking application in the preferred embodiment is markup language based, such as hypertext markup language (“HTML”), extensible markup language (“XML”) or wireless markup language (“WML”), and operates with markup languages that use syntactically delimited characters added to the data of a document to represent the structure of the document. A number of Web server applications and Web client or browser applications are commercially available, such those available from Mozilla and Microsoft.

The operating system and various applications/modules and/or data can be stored on the hard disk of the hard disk drive, the optical disk of the optical disk drive and/or the magnetic disk of the magnetic disk drive.

A computer system can operate in a networked environment using logical connections to one or more client computers and/or one or more database systems, such as one or more remote computers or networks. A computer may be logically connected to one or more client computers and/or database systems under any known method of permitting computers to communicate, for example through a network such as a local area network (“LAN”) and/or a wide area network (“WAN”) including, for example, the Internet. Such networking environments are well known including wired and wireless enterprise-wide computer networks, intranets, extranets, and the Internet. Other embodiments include other types of communication networks such as telecommunications networks, cellular networks, paging networks, and other mobile networks. The information sent or received via the communications channel may, or may not be encrypted. When used in a LAN networking environment, a computer is connected to the LAN through an adapter or network interface card (communicatively linked to the system bus). When used in a WAN networking environment, a computer may include an interface and modem or other device, such as a network interface card, for establishing communications over the WAN/Internet.

In a networked environment, program modules, application programs, or data, or portions thereof, can be stored in a computer for provision to the networked computers. In one embodiment, the computer is communicatively linked through a network with TCP/IP middle layer network protocols; however, other similar network protocol layers are used in other embodiments, such as user datagram protocol (“UDP”). Those skilled in the relevant art will readily recognize that these network connections are only some examples of establishing communications links between computers, and other links may be used, including wireless links.

While in most instances, a computer will operate automatically, where an end user application interface is provided, a user can enter commands and information into the computer through a user application interface including input devices, such as a keyboard, and a pointing device, such as a mouse. Other input devices can include a microphone, joystick, scanner, etc. These and other input devices are connected to the processing unit through the user application interface, such as a serial port interface that couples to the system bus, although other interfaces, such as a parallel port, a game port, or a wireless interface, or a universal serial bus (“USB”) can be used. A monitor or other display device is coupled to the bus via a video interface, such as a video adapter (not shown). The computer can include other output devices, such as speakers, printers, etc.

It is to be fully understood that the present methods, systems and devices also may be implemented as a computer program product that comprises a computer program mechanism embedded in a computer readable storage medium. For instance, the computer program product could contain program modules. These program modules may be stored on CD-ROM, DVD, magnetic disk storage product, flash media or any other computer readable data or program storage product. The software modules in the computer program product may also be distributed electronically, via the Internet or otherwise, by transmission of a data signal (in which the software modules are embedded) such as embodied in a carrier wave.

For instance, the foregoing detailed description has set forth various embodiments of the devices and/or processes via the use of examples. Insofar as such examples contain one or more functions and/or operations, it will be understood by those skilled in the art that each function and/or operation within such examples can be implemented, individually and/or collectively, by a wide range of hardware, software, firmware, or virtually any combination thereof. In one embodiment, the present subject matter may be implemented via ASICs. However, those skilled in the art will recognize that the embodiments disclosed herein, in whole or in part, can be equivalently implemented in standard integrated circuits, as one or more computer programs running on one or more computers (e.g., as one or more programs running on one or more computer systems), as one or more programs running on one or more controllers (e.g., microcontrollers) as one or more programs running on one or more processors (e.g., microprocessors), as firmware, or as virtually any combination thereof, and that designing the circuitry and/or writing the code for the software and or firmware would be well within the skill of one of ordinary skill in the art in light of this disclosure.

In addition, those skilled in the art will appreciate that the mechanisms taught herein are capable of being distributed as a program product in a variety of forms, and that an illustrative embodiment applies equally regardless of the particular type of signal bearing media used to actually carry out the distribution. Examples of signal bearing media include, but are not limited to, the following: recordable type media such as floppy disks, hard disk drives, CD ROMs, digital tape, flash drives and computer memory; and transmission type media such as digital and analog communication links using TDM or IP based communication links (e.g., packet links).

While the forms of node/apparatus, method and system described herein constitute preferred embodiments of this invention, it is to be understood that the invention is not limited to these precise forms. As will be apparent to those skilled in the art, the various embodiments described above can be combined to provide further embodiments. Aspects of the present systems, methods and nodes (including specific components thereof) can be modified, if necessary, to best employ the systems, methods, nodes and components and concepts of the invention. These aspects are considered fully within the scope of the invention as claimed. For example, the various methods described above may omit some acts, include other acts, and/or execute acts in a different order than set out in the illustrated embodiments.

Further, in the methods taught herein, the various acts may be performed in a different order than that illustrated and described. Additionally, the methods can omit some acts, and/or employ additional acts.

### EXAMPLES

### Example 1

### Measuring Voltage

The sensor voltage is measured across the external capacitance between nodes A and B. The voltage is buffered by a high-input impedance voltage follower using an Intersil CA3140 op-amp. The op-amp uses two nine volt batteries providing supply voltages of +/−9 V where the common mode voltage is referenced to the line voltage (hot conductor). The output of the buffer is connected to an Agilent DVM model 34401A which is used to record the sensor voltage. Since the DVM loads the sensor, the measurement model preferably includes compensation for Rm and Cm, the effective input resistance and capacitance of the meter. For this example, Rm is 10 Mohm and Cm is 370 pF. The DVM has analog to digital converters (ADC's) which are floating relative to the potential of the high voltage line. The maximum differential voltage between the input of the meter and ground (neutral) is rated for 500 VAC. This limitation can be removed using an optocoupler.

Three silver mica 130 pF capacitors are used for the calibrated shunt capacitances C₁, C₂, and C₃. For the first set of experimental data, the C₁ is 130 pF and a series of measurements are made for different input voltages ranging from 10 VAC to 130 VAC. The corresponding voltages generate a vector of voltage values called V₁. After the first set of sensing voltages V₁ are made, two additional sets of measurements are made with C₁ plus C₂, and C₁ plus C₂ plus C₃, respectively. The corresponding sensor voltages are called V₂ and V₃. The measurement results are tabulated in Table I.

TABLE I
MEASURED SENSING VOLTAGES
FOR DIFFERENT CAPACITANCES.

| Vᵢₙ (V) | V₁ (V) | V₂ (V) | V₃ (V) |
|---|---|---|---|
| 10 | 0.177 | 0.1385 | 0.1074 |
| 20.2 | 0.363 | 0.2733 | 0.21929 |
| 30.1 | 0.5429 | 0.4083 | 0.3274 |
| 40 | 0.7236 | 0.5439 | 0.4359 |
| 50.1 | 0.9075 | 0.6815 | 0.5469 |
| 60 | 1.085 | 0.619 | 0.6559 |
| 70.1 | 1.2712 | 0.957 | 0.7627 |
| 80 | 1.436 | 1.1 | 0.86 |
| 90 | 1.61 | 1.215 | 0.97 |
| 100 | 1.819 | 1.374 | 1.0924 |
| 110.2 | 2.004 | 1.5011 | 1.2042 |
| 120 | 2.1876 | 1.646 | 1.3122 |
| 130.1 | 2.3698 | 1.775 | 1.4229 |

### Example 2

### Linearity Test

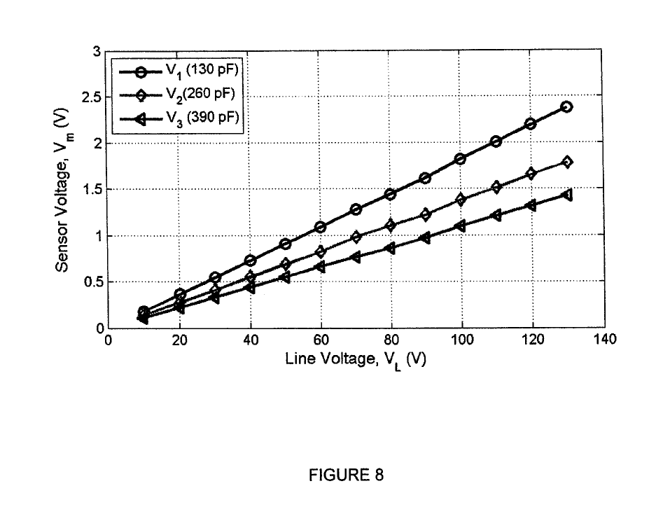

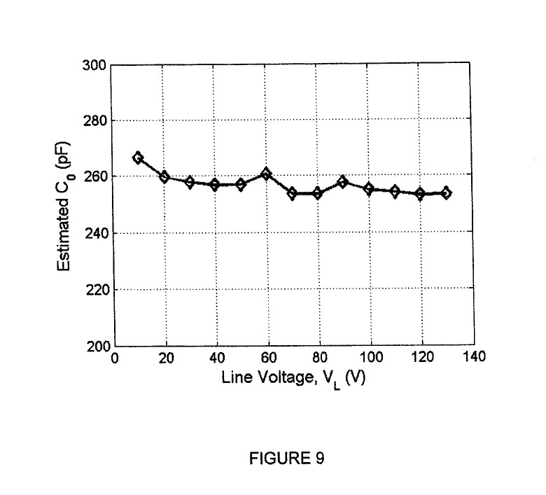

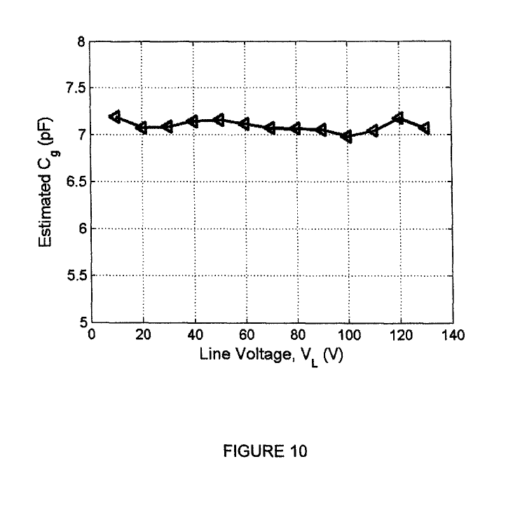

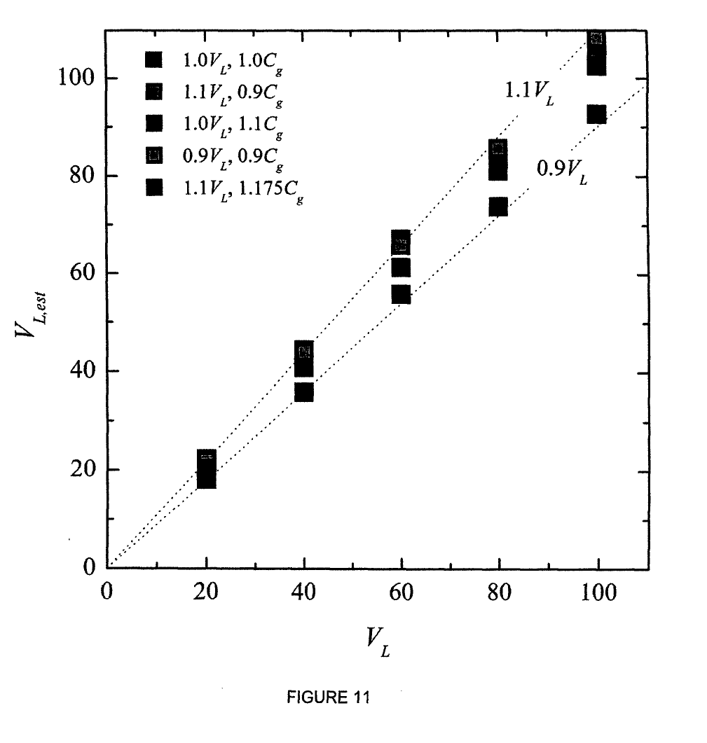

To check the linearity of the measured sensing voltages, a figure is plotted based on input voltages versus sensing voltages. This is shown graphically in FIG. 8. From this figure, it is clear that the sensing voltages, V₁, V₂ and V₃ are linear.

### Example 3

### Factory Calibration to Estimate the Unknown Capacitances

A numerical method is developed to solve for the unknown values (Cₒ, C_{g}, and V_{L}) by applying three parallel capacitances successively across the voltage sensor on the high-voltage line. This numerical method has been implemented in Matlab code to validate the measurement method. If the first capacitance C₁ is connected across Cₒ, then the voltage V₁ from node A to node B can be calculated from the following equation: It is to be noted that the high impedance buffer removes the contribution of Cₘ and the input capacitance of the buffer, from hereon, is assumed to be absorbed in the value of Cₒ.

$${V}_{1} = {V}_{L} \frac{{C}_{g}}{{C}_{g} + {C}_{0} + C} . \qquad ( 1 )$$

Similarly, if the second and third capacitances are connected, the corresponding voltages V₂ and V₃ are:

$$\begin{matrix}{V}_{2} = {V}_{in} \frac{{C}_{g}}{{C}_{g} + {C}_{0} + 2 C} & ( 2 ) \\ {V}_{3} = {V}_{in} \frac{{C}_{g}}{{C}_{g} + {C}_{0} + 3 C} & ( 3 ) \\ {V}_{2} = {V}_{L} \frac{{C}_{g}}{{C}_{g} + {C}_{0} + 2 C} & \\ {V}_{3} = {V}_{L} \frac{{C}_{g}}{{C}_{g} + {C}_{0} + 3 C} . & \\ {V}_{2} = {V}_{L} \frac{{C}_{g}}{{C}_{g} + {C}_{0} + 2 C} & ( 2 ) \\ {V}_{3} = {V}_{L} \frac{{C}_{g}}{{C}_{g} + {C}_{0} + 3 C} . & ( 3 )\end{matrix}$$

By simplifying equation 1 to 3 the following is attained:

V₁C_{g}−VᵢₙC_{g}+V₁Cₒ+V₁C0 (4)

V₂C_{g}−VᵢₙC_{g}+V₂Cₒ+2V₂C=0 (5)

V₃C_{g}−VᵢₙC_{g}+V₃Cₒ+3V₃C=0. (6)

V₁C_{g}−V_{L}C_{g}+V₁Cₒ+V₁C=0

V₂C_{g}−V_{L}C_{g}+V₂Cₒ+2V₂C=0

V₃C_{g}−V_{L}C_{g}+V₃Cₒ+3V₃C=0.

V₁C_{g}−V_{L}C_{g}+V₁Cₒ+V₁C=0 (4)

V₂C_{g}−V_{L}C_{g}+V₂Cₒ+2V₂C=0 (5)

V₃C_{g}−V_{L}C_{g}+V₃Cₒ+3V₃C=0. (6)

In equation (4), (5) and (6), the measured (detected) voltages V₁, V₂, V₃ and the external capacitances are known. Therefore, in these equations there are three unknowns, C_{g}, Cₒ and V_{L}. These three equations are non-linear and cannot be used to uniquely solve for the three unknown variables. However if, as in a factory calibration, a known line voltage V_{L} is applied to the system the values of C_{g} and Cₒ can be uniquely determined preferably by using a root finder algorithm and a mean square error (MSE) objective function. For example, a root finder algorithm—may be used in this case and initial estimates for the unknown values are provided. The objective function is nonlinear with local minima and selecting appropriate initial values is generally desired in order to get convergence to the global minimum.

By using equation (4), (5) and (6) and the measured sensing voltages from Table I, values for C_{g} and Cₒ can be found. The estimated values from Matlab are tabulated in Table II. (Thomas, I recommend deleting the 4^{th} column from table II)

TABLE II
ESTIMATED VALUES OF C_{g}, C₀ AND Vᵢₙ.

| Vᵢₙ (V) | C_{g} (pF) | C₀ (pF) | Vᵢn (V) |
|---|---|---|---|
| 10 | 7.1842 | 266.6186 | 10.0544 |
| 20.2 | 7.0680 | 259.6052 | 20.3703 |
| 30.1 | 7.0815 | 257.8584 | 30.2750 |
| 40 | 7.1374 | 256.7471 | 39.9298 |
| 50.1 | 7.1500 | 256.9363 | 50.0011 |
| 60 | 7.1094 | 260.5893 | 60.7213 |
| 70.1 | 7.0644 | 253.4807 | 70.3433 |
| 80 | 7.0584 | 253.5380 | 79.9556 |
| 90 | 7.0466 | 257.5662 | 90.2422 |
| 100 | 6.9778 | 254.8648 | 102.3179 |
| 110.2 | 7.0367 | 254.0642 | 111.3239 |
| 120 | 7.1688 | 253.0786 | 119.1870 |
| 130.1 | 7.0631 | 253.3477 | 130.9330 |

The mean of the estimated values for Cₒ and C_{g} are 257 pF and 7.1 pF respectively. The standard deviation of the estimated values for Cₒ and C_{g} are 3.9 pF and 0.06 pF, respectively, which are very reasonable. Therefore these measurements show that it is possible to conduct a factory calibration to determine the unknown capacitances C_{g} and Cₒ and that the values of these capacitances are independent of the applied line voltage. The value of C_{g} is sensitive to the geometry of the conductors, for example the conductor spacing and the conductor height above ground. Because of this sensitivity, the value of C_{g} determined from the factory calibration may not be well matched to the value of C_{g} when the voltage sensing unit is deployed in the field. The value of Cₒ, however is much less sensitive to the conductor geometry and its the value in the field can be accurately estimated from a prior factory calibration.

### Example 4

### Blind Estimates of Line Voltages

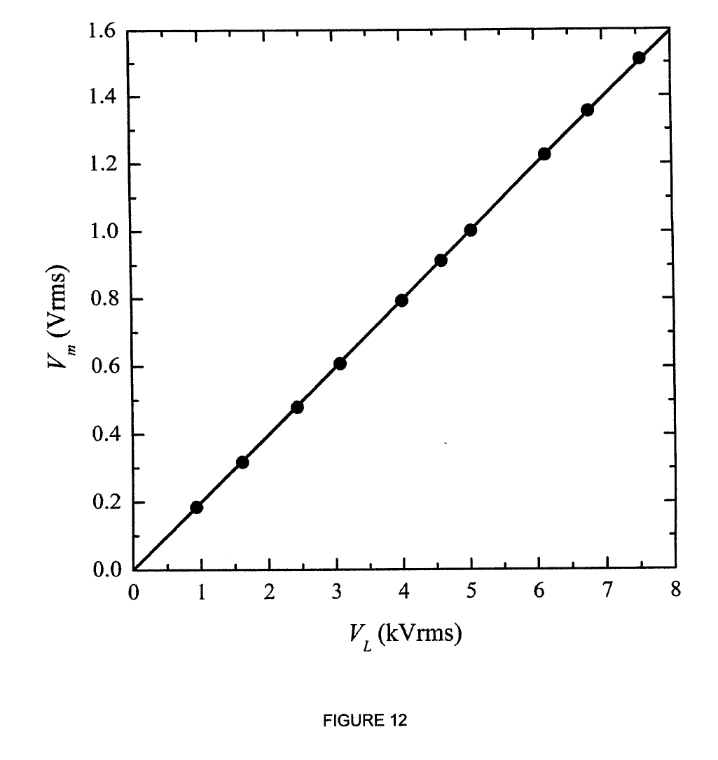

Having completed a prior factory calibration to accurately determine Cₒ, the only unknowns in equation (5) [page 17] relating Vₘ to the V_{L} are the line voltage V_{L} and C_{g}. Non-linear fits of Vₘ measured as a function of C_{b} fit to equation (5) will result in best-fit values of both C_{g} and V_{L}. FIG. 12 compares the estimated line voltage determined using the voltage sensing unit to the known applied line voltage. In this example, Cₒ was determined from a factory calibration to be 9.18 pF. Non-linear fits of the collected data to equation (5) C_{g} values close to 1.00 pF and estimated line voltages that were within 10% of the applied line voltages. The accuracy with which V_{L} can be estimated is proportional to C_{g}/Cₒ and to the accuracy with which Cₒ is known. Therefore, it is crucial that both an accurate factory calibration be performed to determine Cₒ and that the voltage sensing unit be designed such that C_{g}/Cₒ be as small as is practical.

### Example 5

### Lineary of the High-Voltage Configuration

With Cₒ=9.18 pF and C_{g}=1.00 pF as in Example 4 above, the line voltage is reduced by less than one tenth when C_{b} is set to zero. As a result, modest line voltages of just over 100 Vrms would be sufficient to saturate the buffer of the voltage sensing unit making the device useless as a high-voltage sensor. In this example, an additional secondary capacitive divider was added as shown in FIG. 7 using the values C_{d1}=0.5 pF and C_{d2}=130 pF to further reduce Vₘ by a factor of 1/260 without altering the sensitivity of the sensor.

FIG. 13 shows the measured voltage Vₘ plotted as a function of the V_{L} up to 7.5 kVrms. The obvious linear relationship shows that Vₘ is directly proportional to the line voltage as desired. Furthermore, the sensor buffer will not saturate until a line voltage of approximately 60 kVrms is reached. If even larger line voltages need to be measured, one simply has to use larger values of C_{d2}. Increasing C_{d2} enables larger line voltages to be measured by does not alter the sensor sensitivity.

These and other changes can be made to the present systems, methods and articles in light of the above description. In general, in the following claims, the terms used should not be construed to limit the invention to the specific embodiments disclosed in the specification and the claims, but should be construed to include all possible embodiments along with the full scope of equivalents to which such claims are entitled. Accordingly, the invention is not limited by the disclosure, but instead its scope is to be determined entirely by the following claims.

1. A method for sensing a voltage of a power line using a single contact, the method comprising:
providing a voltage sensing unit, the voltage sensing unit comprising a shielded enclosure hosting a bank of capacitors comprising at least two capacitors mounted in parallel, each of the at least two capacitors being controlled by a corresponding switch, the bank of capacitors having a first connecting contact and a second connecting contact;
operatively connecting one of the two connecting contact of the voltage sensing unit to the line;
for each given capacitor of the at least two capacitors:
selecting the given capacitor using a corresponding switch;
measuring a corresponding voltage between the two connecting contacts; and
determining the voltage of the line using the measured voltages.

2. The method of claim 1, wherein the measuring of the given voltage at said selected capacitor comprises performing an amplification using a measurement amplifier operatively coupled to the two connecting contacts of the bank of capacitors, the measurement amplifier having a corresponding impedance, further wherein the determining of the voltage of the line is performing using the measured voltages and the corresponding impedance of the measurement amplifier.

3. A voltage sensing unit for sensing a voltage of a power line using a single contact, the voltage sensing unit comprising:
a) a shielded enclosure comprising a bank of capacitors, the bank of capacitors comprising at least two capacitors mounted in parallel, each of the at least two capacitors being controlled by a corresponding switch, the bank of capacitors having a first connecting contact and a second connecting contact;
b) a line connector operatively connected to one of the two connecting contacts for operatively connecting the voltage sensing unit to the line; and
c) two voltage measuring contacts connected to the first connecting contact and the second connecting contact, the two voltage measuring contacts for receiving a voltage measuring unit.

4. The voltage sensing unit for sensing a voltage as claimed in claim 3, further comprising a voltage measuring unit operatively connected to the two voltage measuring contacts.

5. The voltage sensing unit as claimed in claim 4, wherein the voltage measuring unit comprises a measurement amplifier.

6. The sensing unit of claim 3 which is capable of taking measurements over selected time intervals.

7. The sensing unit of claim 3 wherein the voltage sensing unit is configured for removable engagement with the power line at the single contact.

8. The sensing unit of claim 3 wherein the power line is one which is selected from the group consisting of a primary supply line and a secondary supply line.

9. A system for sensing a voltage of a power line using a single contact on said line, which comprises:
a) a voltage sensing unit for sensing a voltage of a power line using a single contact, the voltage sensing unit comprising:
a shielded enclosure comprising a bank of capacitors, the bank of capacitors comprising at least two capacitors mounted in parallel, each of the at least two capacitors being controlled by a corresponding switch, the bank of capacitors having a first connecting contact and a second connecting contact;
a line connector operatively connected to one of the two connecting contacts for operatively connecting the voltage sensing unit to the line; and
two voltage measuring contacts connected to the first connecting contact and the second connecting contact, the two voltage measuring contacts for receiving a voltage measuring unit;
b) a means to calibrate the at least two capacitors;
c) a microcontroller circuit;
d) a transceiver;
e) storage memory for data; and
f) a means to communicate voltage data.

10. A method for sensing a voltage of a power line using a single contact, the method comprising:
providing a voltage sensing unit, the voltage sensing unit comprising a shielded enclosure hosting a bank of capacitors comprising at least two capacitors mounted in parallel, each of the at least two capacitors being controlled by a corresponding switch, and
determining an unknown stray capacitance between a neutral conductor and the voltage sensing unit by measuring a set of voltages corresponding to differing switch positions and fitting measurements so determined to a non-linear circuit model.

11. A method for sensing a voltage of a power line using a single contact, the method comprising:
providing a voltage sensing unit, the voltage sensing unit comprising a shielded enclosure hosting a bank of resistors comprising at least two resistors mounted in parallel, each of the at least two resistors being controlled by a corresponding switch, and
determining an unknown stray capacitance between a neutral conductor and the voltage sensing unit by measuring a set of voltages corresponding to differing switch positions and fitting measurements so determined to a non-linear circuit model.

12. A method for sensing a voltage of a power line using a single contact, the method comprising:
providing a voltage sensing unit, the voltage sensing unit comprising a shielded enclosure hosting a bank of capacitors and/or resistors comprising at least two capacitors and/or resistors mounted in parallel, each of the at least two capacitors and/or resistors being controlled by a corresponding switch, and
determining an unknown stray capacitance between a neutral conductor and the voltage sensing unit by measuring a set of voltages corresponding to differing switch positions and fitting measurements so determined to a non-linear circuit model.

13. The method of claim 12, the method further comprising measuring the current on the power line and then combining the current measurement and a voltage measurement in the set of voltages to determine a power factor of the power line.

14. The method of claim 13 wherein three single contact sensors are used in three phase measurements.

15. The method of claim 14 wherein voltage measurements of the three single contact sensors are compared to measure voltage at each phase.

16. The method of claim 14 wherein voltage measurements of the three sensors are compared to measure voltage at each phase and current is measured at each phase and thereafter a power factor is calculated for each phase.

17. A method of ascertaining an unknown line voltage at point X on a power line within an electrical grid which comprises:
a) collecting raw voltage at or about Point X using a sensor;
b) gathering additional data from data collection sources upstream or downstream to Point X;
c) using raw voltage, and environment and line data to calculate a voltage range at Point X; and
d) using constraining data sequentially to bind the voltage range from a determined range of possibilities to a likely absolute voltage measurement.

18. A computer implemented method of computing voltage at a Point X on a power line within an electrical grid wherein there is a substation with voltage measuring capacity but no downstream voltage measuring means, the method comprising:
i) collecting raw voltage data in a voltage sensing unit on the power line at Point X;
ii) transmitting the raw voltage data to a server on a computing system remote from the sensor, said computing system comprising a microprocessor;
iii) gathering additional data from substation to Point X;
iv) using the raw voltage, and environment and line data to calculate a voltage range at Point X; and
v) using constraining data sequentially to bind the voltage range from a determined range of possibilities to a likely absolute voltage measurement at Point X.

19. A computer implemented method of computing voltage at a Point X on a power line within an electrical grid wherein there is a substation with voltage measuring capacity and there is at least one downstream voltage measuring means, the method comprising:
i) collecting raw voltage data in a voltage sensing unit on the power line;
ii) transmitting the raw voltage data to a server on a computing system remote from the sensor, said computing system comprising a microprocessor; and
iii) gathering additional data from substation and at least one downstream source to Point X;
iv) using raw voltage, and environment and line data to calculate a voltage range at Point X; and
v) using constraining data sequentially to bind the voltage range from a determined range of possibilities to a likely absolute voltage measurement.

20. The method of claim 1 wherein the voltage sensing unit is suspended from a neutral conductor.

21. The method of claim 1 wherein the voltage sensing unit is suspended from a high-voltage conductor.

22. The method of claim 1 wherein the voltage sensing unit comprises a sensing plate and wherein a shape of the sensing plate is selected from the group consisting of conical, spherical, semi-spherical, and tapered.

23. The method of claim 1 wherein the voltage sensing unit comprises a flat sensing disk on a post.

24. The voltage sensing unit of claim 3 wherein the voltage sensor is suspended from a neutral conductor.

25. The voltage sensing unit of claim 3 wherein the voltage sensing unit is suspended from a high-voltage conductor.

26. The voltage sensing unit of claim 3 wherein the voltage sensing unit comprises a sensing plate and wherein the shape of the plate is selected from group consisting of conical, spherical, semi-spherical, and tapered.

27. The voltage sensing unit of claim 3 wherein the voltage sensing unit comprises a flat sensing disk on a post.

28. The voltage sensing unit of claim 3 wherein the voltage sensing unit is configured for high-voltage measurements using an additional secondary capacitive divider.

29. The method of claim 1 wherein the voltage sensing unit is configured for high-voltage measurements using an additional secondary capacitive divider.
